(19) United States
(12) Patent Application Publication
(10) Pub. No.: US 2023/0082905 A1
(43) Pub. Date: Mar. 16, 2023

(54) RADIO FREQUENCY POWER AMPLIFIER

(71) Applicant: STMicroelectronics International N.V., Geneva (CH)

(72) Inventors: Herve Guegnaud, Maurepas (FR); Stephanie Venec, Paris (FR); Guillaume Blamon, Courbevoie (FR)

(21) Appl. No.: 17/800,290

(22) PCT Filed: Feb. 15, 2021
(86) PCT No.: PCT/EP2021/053677

§ 371 Date: Aug. 17, 2022

(30) Foreign Application Priority Data
Feb. 17, 2020 (EP) 20157684.0

(51) Int. Cl. H03F 1/52; H03F 3/24

(52) U.S. Cl. CPC H03F 1/523; H03F 3/245; H03F 2200/451; H03F 2200/211; H03F 2200/393; H03F 2200/426; H03F 2200/78; H03F 2200/135

(57) ABSTRACT

According to one aspect, an integrated circuit includes a power amplifier having a succession of at least two amplifier stages. The two amplifier stages include a first amplifier stage configured to receive a radio frequency signal as input and a last amplifier stage configured to deliver as an output of an amplified radio frequency signal. The power amplifier further includes a safety circuit with a control circuit configured to compare the amplified radio frequency signal voltage with a threshold voltage. The safety circuit further comprises a gain reduction circuit configured to reduce a bias voltage of an upstream amplifier stage of the last amplifier stage when the amplified radio frequency signal voltage is greater than the threshold voltage.

### CROSS-REFERENCE TO RELATED APPLICATIONS

This application is a national stage of International Application No. PCT/EP2021/053677, filed on Feb. 15, 2021, which claims priority to European Patent Application No. 20157684.0, filed on Feb. 17, 2020, which applications are hereby incorporated by reference herein in their entirety.

### TECHNICAL FIELD

Embodiments and implementations relate to the radio frequency power amplifiers, in particular the power amplifiers with multiple amplifier stages.

### BACKGROUND

A radio frequency power amplifier is generally used to amplify a radio frequency signal before delivering it to a radio antenna.

The multi-stage power amplifiers are generally used to obtain a high gain between a signal arriving at the input of the power amplifier and a signal at the output of the power amplifier. In particular, a multi-stage power amplifier can comprise a driver stage and a power stage.

The last amplifier stage, in particular the power stage, comprises an output connected to a radio frequency antenna.

The multi-stage amplifiers can be used in devices intended for the Internet of Things (also known by the acronym IOT).

Each amplifier stage can be a CMOS amplifier (acronym for “Complementary Metal Oxide Semiconductor”).

The radio antenna has an impedance which can vary according to the environment in which the radio antenna is placed. In particular, in some environments, particularly when the radio antenna is located in the vicinity of a metal element, the impedance thereof may vary such that the antenna is no longer adapted relative to the power amplifier. In other words, the antenna has a high standing wave ratio.

These variations in impedances can cause overvoltages at the output of the power amplifier relative to a nominal operation of the antenna.

However, the last amplifier stage of the power amplifier is not always configured to undergo such overvoltages. In particular, the last amplifier stage can comprise transistors having a safe operating range below these overvoltages. Thus, the overvoltages can damage the last amplifier stage of the power amplifier.

In order to solve this drawback, the last amplifier stage of some power amplifiers comprises a dedicated high-voltage component, such as for example LDMOS transistors or MOS transistors with a thick oxide. Such a dedicated high-voltage component has in particular a breakdown voltage which is greater than 15V. Nevertheless, such high frequency components are less efficient at high frequencies, and the manufacture thereof is more expensive. There are also efficient transistors such as GaAs transistors, but these efficient transistors have a higher manufacturing cost.

Alternatively, it is possible to increase the number of cascaded transistors of the last amplifier stage. Such a solution has the drawback of increasing the space required for the last amplifier stage.

Moreover, it is possible to implement a clipping allowing limiting the overvoltages at the output of the last amplifier stage. Nevertheless, this solution may degrade the performances of the amplifier.

There is therefore a need to propose a power amplifier which is protected against the overvoltages which may arise at the output of the last amplifier stage thereof and having good performances while being inexpensive.

### SUMMARY

According to one aspect, there an integrated circuit is proposed comprising a power amplifier including:
a succession of at least two amplifier stages including a first amplifier stage configured to receive as input a radio frequency signal and a last amplifier stage configured to deliver as output an amplified radio frequency signal,
a safety circuit comprising:
   control circuit configured to compare a voltage of the amplified radio frequency signal with a threshold voltage,
   gain reduction circuit configured to reduce a bias voltage of an amplifier stage upstream of the last amplifier stage when the voltage of the amplified radio frequency signal is greater than the threshold voltage.

The amplifier stages allow amplifying a radio frequency signal received by the first stage.

The voltage at the output of the last stage can be equal to the sum of a direct voltage at the drain of the last amplifier stage and of the voltage swing of the amplified radio frequency signal.

Only the last amplifier stage can be connected to a radio antenna. Thus, only the last amplifier stage should be protected from overvoltages.

The control circuit is configured to measure the amplified radio frequency signal at the output of the last amplifier stage then to compare this amplified radio frequency signal with the threshold voltage.

The control circuit allows controlling the voltage of the amplified signal at the output of the last amplifier stage by comparing it with a threshold voltage.

Moreover, the gain reduction circuit allows reducing the gain of an amplifier stage upstream of the last amplifier stage when the voltage at the output of the last amplifier stage exceeds the threshold voltage.

In particular, when the power amplifier includes only two amplifier stages, the gain reduction circuit allows reducing the gain of the first amplifier stage. Nevertheless, when the power amplifier includes more than two amplifier stages, the gain reduction circuit can allow reducing the gain of the first amplifier stage or else the gain of an intermediate amplifier stage between the first amplifier stage and the last amplifier stage.

Preferably, the threshold voltage is selected to be less than a minimum voltage which can damage the last amplifier stage.

By reducing the gain of an upstream amplifier stage, the voltage swing of the amplified radio frequency signal is also reduced. Thus, by reducing the gain of an upstream amplifier stage, the maximum voltage of the amplified radio frequency signal decreases to be below the threshold voltage.

This allows maintaining the voltage of the amplified radio frequency signal below a voltage which can damage the last amplifier stage.

Thus, the safety circuit allows protecting the last amplifier stage.

Furthermore, the safety circuit does not interfere with the performances of the power amplifier. Indeed, the gain reduction circuit does not intervene during a nominal operation of the antenna.

Furthermore, the fact of reducing the gain, not of the last amplifier stage, but of a stage upstream of the last amplifier stage, allows obtaining a rapid amplified signal voltage reduction.

The safety circuit allows the use of simple and inexpensive amplifier stages.

Furthermore, this safety circuit is also inexpensive to manufacture.

In an advantageous embodiment, the control circuit comprises a threshold voltage generator.

Advantageously, the threshold voltage generator comprises a current source and a resistor. Preferably, this current source and/or this resistor are modifiable so as to be able to adjust the threshold voltage.

Preferably, the control circuit further comprise:
a rectifier configured to rectify the voltage of the amplified radio frequency signal,
a comparator configured to compare the rectified voltage of the amplified radio frequency signal with the threshold voltage and to generate as output a signal when the rectified voltage of the amplified radio frequency signal is greater than the threshold voltage,
a filter configured to remove the radio frequencies from the signal at the output of the comparator.

In an advantageous embodiment, the gain reduction circuit is configured to reduce the gain of the upstream amplifier stage by reducing the bias voltage of this amplifier stage.

Preferably, the gain reduction circuit comprises amplification circuit configured to amplify the signal at the output of the filter of the control circuit and to deliver this amplified signal to the input of said upstream amplifier stage in order to reduce the gate voltage of an input transistor of said upstream amplifier stage.

In an advantageous embodiment, the power amplifier comprises only two amplifier stages, the first amplifier stage being a driver stage and the last amplifier stage being a power stage, the gain reduction circuit being configured to reduce a bias voltage of the driver stage when the voltage of the amplified radio frequency signal is greater than the threshold voltage.

Alternatively, the power amplifier can for example comprise three amplifier stages. A first amplifier stage can be a pre-driver stage, a second amplifier stage can be a driver stage, and a third stage can be a power stage. In this case, the gain reduction circuit can be configured to reduce the gain of the pre-driver stage or that of the driver stage.

According to another aspect, an object is proposed comprising:
a radio antenna,
an integrated circuit as previously described, the power amplifier being connected to the radio antenna so as to be able to deliver to the radio antenna an amplified radio frequency signal from a radio frequency signal received at the input of this power amplifier.

### BRIEF DESCRIPTION OF THE DRAWINGS

Other advantages and features of the invention will appear on examination of the detailed description of embodiments and implementations, which are in no way limiting, and of the appended drawings in which:

FIG. 1 is a block diagram of an embodiment integrated circuit; and

FIG. 2 is a block diagram of an embodiment integrated circuit.

### DETAILED DESCRIPTION OF ILLUSTRATIVE EMBODIMENTS

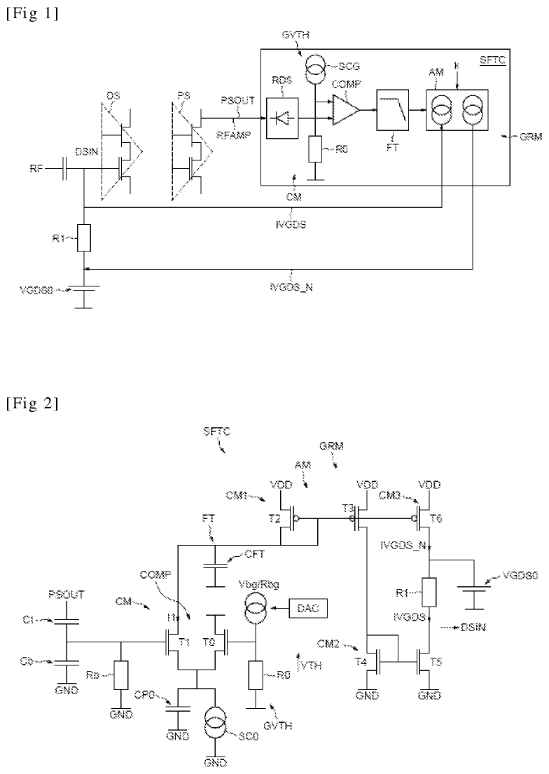

FIG. 1 illustrates an integrated circuit according to an embodiment of the invention.

The integrated circuit comprises a power amplifier AMP. The power amplifier AMP is configured to amplify a radio frequency RF signal received at the input DSIN and deliver the amplified radio frequency signal at the output PSOUT. This amplified radio frequency signal can be delivered to a radio antenna (not represented).

Such a power amplifier AMP can in particular be integrated into an object comprising a radio antenna, in particular so as to be able to be used within the framework of the Internet of Things.

In the represented embodiment, the power amplifier AMP includes two amplifier stages DS, PS. A first amplifier stage is a driver stage DS. The second amplifier is a power stage PS.

The first amplifier stage, the driver stage DS, is placed upstream of the second amplifier stage, the power stage PS.

In particular, the driver stage DS is configured to receive as input DSIN the radio frequency signal RF, and the power stage PS is configured to deliver the amplified radio frequency signal RFAMP.

The driver stage DS and the power stage PS each comprise two cascaded transistors to amplify the signal that they receive as input.

The driver stage DS is configured to receive a bias voltage on the gate of an input transistor of this driver stage.

In nominal operation, the bias voltage is defined by a direct voltage source VGDS0 and by a resistor R1. The resistance R1 can be in the range of 1 kΩ.

The power amplifier AMP also comprises a safety circuit SFTC. The safety circuit SFTC comprises control circuit CM and gain reduction circuit GRM.

These circuit CM, GRM are configured to regulate the gain of the power amplifier AMP depending on the voltage of the amplified radio frequency signal RFAMP at the output PSOUT of the power stage PS.

In particular, the control circuit (CM) is configured to detect an overvoltage of the amplified radio frequency signal RFAMP.

The control circuit CM comprise a rectifier RDS configured to receive the amplified radio frequency signal RFAMP and to deliver a direct signal from this amplified radio frequency signal RFAMP.

The control circuit CM also comprise a threshold voltage generator GVTH. The threshold voltage generator GVTH is configured to be able to generate a threshold voltage VTH.

In particular, the threshold voltage generator GVTH comprises a current source SCG and a resistor R0 in series. In particular, the resistor R0 has a first terminal which is connected to the current source and a second terminal which is connected to ground GND. As represented in FIG. 2, the gate of the second transistor T0 is connected to the current source SCG and to the first terminal of the resistor R0 so as to receive the threshold voltage VTH.

In particular, the current source is configured to deliver a current equal to Vbg/Rbg, where Vbg and Rbg are voltage and resistance parameters of the current source. Thus, the threshold voltage VTH which can be received by the gate of the second transistor is equal to Vbg/Rbg*R0.

Preferably, the threshold voltage VTH can be adjusted using a digital-to-analogue converter DAC allowing setting the current delivered by the current source SCG and/or the value of the resistance R0.

In the embodiment shown in FIG. 1, the digital-to-analogue converter DAC allows setting the current delivered by the current source SCG.

In particular, the threshold voltage is selected to be less than a voltage at the output PSOUT of the power stage PS which can damage the latter. For example, the threshold voltage can be in the volt range.

Furthermore, the control circuit CM also comprise a comparator COMP configured to compare the direct signal derived from the amplified radio frequency signal with the threshold voltage VTH.

As represented in FIG. 2, the comparator can be made from two transistors T1, T0, in particular NMOS transistors. The transistors T1, T0 each have a source which is connected to the source of the other transistor.

A first transistor T1 has a gate configured to receive the amplified radio frequency signal RFAMP.

More particularly, a capacitive divider DCP can be provided upstream of the gate of the first transistor T1 in order to reduce the voltage of the amplified radio frequency signal RFAMP in order to adapt it to the first transistor T1. This capacitive divider DCP comprises two capacitors Ct, Cb in series.

A first capacitor Ct has a first terminal connected to the output of the power stage DS, in particular to a drain of an output transistor of the power stage. Thus, this first capacitor Ct is configured to receive a voltage VDRAIN from the output of the power stage.

The first capacitor Ct also has a second terminal connected to a first terminal of a second capacitor Cb of the capacitive divider DCP.

The second capacitor Cb has a second terminal connected to a ground GND.

The gate of the first transistor T1 is connected to the second terminal of the capacitor Ct and to the first terminal of the capacitor Cb.

Furthermore, a resistor Rb has a first terminal connected to the gate of the first transistor, to the second terminal of the capacitor Ct and to the first terminal of the capacitor Cb.

Moreover, the second transistor T0 of the comparator has a gate configured to receive the threshold voltage VTH.

Moreover, the source of the first transistor T1 and the source of the second transistor T0 are connected to a current source SC0 and to a capacitor CP0 which are mounted in parallel.

The current source SC0 can for example deliver a current in the range of 10 μA.

The capacitor CP0 can have a capacitance in the range of a few picofarads.

Moreover, the second transistor T0 has a drain connected to a voltage source VDD and the first transistor T1 has a drain forming an output of the comparator.

Thus, when the divided voltage of the amplified radio frequency signal RFAMP received by the gate of the first transistor is greater than the threshold voltage VTH, a current I1 passes through the first transistor T1.

This current I1 therefore allows indicating that the voltage of the radio frequency signal RFAMP is too high.

In order to eliminate certain frequencies from the current I1, the control circuit CM comprise a filter FT, represented in FIG. 1. The filter FT is thus connected to the output of the comparator COMP. This filter FT can be made using a capacitor CFT having a first terminal connected to the drain of the first transistor T1 of the comparator COMP, and a second terminal connected to the ground GND.

Furthermore, the gain reduction circuit GRM comprise circuit AM for amplifying the current I1 delivered by the filter.

These amplification circuit AM comprise two current mirrors CM1, CM2. A first current mirror CM1 comprises two PMOS transistors T2 and T3.

In particular, the transistor T2 has a drain connected to the filter output FT, that is to say to the first terminal of the capacitor CFT. The transistor T2 also has a gate connected to a gate of the transistor T3 and to the drain of the transistor T2. The transistor T2 and the transistor T3 each have a source connected to the voltage source VDD.

A second current mirror CM2 comprises two NMOS transistors T4 and T5.

In particular, the transistor T4 has a drain connected to a drain of the transistor T3 and a source connected to the ground GND. The transistor T4 has a gate connected to a gate of the transistor T5 and to the drain of the transistor T4.

The transistor T5 has a drain connected to the gate of the input transistor of the driver stage and a source connected to the ground.

Thus, the drain of the transistor T5 is connected to the first terminal of the resistor R1.

The two current mirrors CM1, CM2 allow multiplying the current at the output of the filter by the ratios between the transistors T2, T3 and between the transistors T4 and T5.

These two current mirrors CM1, CM2 thus allow generating a current IVGDS at the drain of the transistor T5. This current IVGDS allows reducing the bias voltage of the gate of the input transistor of the driver stage. This current IVGDS will be proportional to the current I1 exiting the filter and at a ratio k equal to a product of the ratios between the transistors T2, T3 and between the transistors T4 and T5.

The current IVGDS through the resistor R1 provides a voltage drop equal to (−k*I1*R1).

Thus, the gate voltage of the driver stage equal to (VGDS0−k*I1*R1) is reduced.

This allows reducing the gain of this driver stage. The reduction of the gain of the driver stage allows reducing the voltage swing of the amplified radio frequency signal. Thus, when the voltage of the amplified radio frequency signal is sufficiently reduced, the voltage of the amplified radio frequency signal at the comparator, that is to say at the gate of the first transistor T1, becomes lower than the threshold voltage VTH. Therefore, the current I1 is no longer generated such that the bias current is that defined by the voltage source VGDS0 and by the resistor R1.

The safety circuit thus allows limiting the voltage of the amplified radio frequency signal below a voltage which could damage the power stage.

Moreover, a current mirror CM3 comprising the transistor T2 and a transistor T6 is provided to create an opposite current IVGDS_N relative to the current IVGDS.

The transistor T6 is a PMOS transistor. This transistor T6 has a gate connected to the gate of the transistor T2, a drain connected to the second terminal of the resistor R1 and to the voltage source which is connected to the voltage source VGDS0. The transistor T6 also has a source connected to the voltage source VDD.

The opposite current IVGDS_N is therefore generated at the drain of the transistor and delivered at the output of the voltage source VGDS0. In this manner, the current VGDS0 will always be close to 0 mA without any disturbance of the voltage source VGDS0.

As previously seen, the safety circuit SFTC allows protecting the last amplifier stage.

Furthermore, the safety circuit SFTC does not interfere with the performance of the power amplifier. Indeed, the gain reduction circuit do not intervene during a nominal operation of the antenna.

Furthermore, reducing the gain, not of the last amplifier stage, but of a stage upstream of the last amplifier stage, allows obtaining a rapid amplified signal voltage reduction.

The safety circuit allows the use of simple and inexpensive amplifier stages.

Furthermore, this safety circuit is also inexpensive to manufacture.

1-8. (canceled)

9. An integrated circuit, comprising:
a power amplifier, comprising:
a first amplifier stage configured to receive an input radio frequency signal;
a last amplifier stage configured to deliver an amplified radio frequency signal, the first amplifier stage and the last amplifier stage arranged in succession to each other, and
a safety circuit, comprising:
a control circuit configured to compare a voltage of the amplified radio frequency signal with a threshold voltage, and
a gain reduction circuit configured to reduce a gain of an upstream amplifier stage to the last amplifier stage in response to the voltage of the amplified radio frequency signal being greater than the threshold voltage.

10. The integrated circuit of claim 9, wherein the control circuit includes a threshold voltage generator circuit configured to generate the threshold voltage.

11. The integrated circuit of claim 10, wherein the threshold voltage generator circuit includes a variable current source and a variable resistor, the threshold voltage being adjustable based on a variation of the variable current source, the variable resistor, or a combination thereof.

12. The integrated circuit of claim 10, wherein the control circuit comprises:
a rectifier configured to generate a rectified voltage of the amplified radio frequency signal;
a comparator circuit configured to:
compare the rectified voltage of the amplified radio frequency signal with the threshold voltage, and
generate an output signal in response to the rectified voltage of the amplified radio frequency signal being greater than the threshold voltage; and
a filter circuit configured to remove radio frequencies of the output signal.

13. The integrated circuit of claim 12, wherein the gain reduction circuit comprises an amplification circuit configured to:
generate an amplified output signal at an output of the filter circuit; and
transfer to an input of the upstream amplifier stage to reduce a gate voltage of an input transistor of the upstream amplifier stage.

14. The integrated circuit of claim 9, wherein the gain reduction circuit is configured to reduce the gain of the upstream amplifier stage by decreasing a bias voltage of the upstream amplifier stage.

15. The integrated circuit of claim 9, wherein the first amplifier stage is a driver stage amplifier and the last amplifier stage is a power stage amplifier, the gain reduction circuit configured to reduce the gain of the driver stage amplifier in response to the voltage of the amplified radio frequency signal is greater than the threshold voltage.

16. A device, comprising:
an antenna; and
an integrated circuit, comprising:
a power amplifier coupled to the antenna and configured to deliver an amplified radio frequency signal to the antenna from an input radio frequency signal received at an input of the power amplifier, the power amplifier comprising:
a first amplifier stage configured to receive the input radio frequency signal;
a last amplifier stage configured to deliver the amplified radio frequency signal to the antenna, the first amplifier stage and the last amplifier stage arranged in succession to each other; and
a safety circuit, comprising:
a control circuit configured to compare a voltage of the amplified radio frequency signal with a threshold voltage, and
a gain reduction circuit configured to reduce a gain of an upstream amplifier stage to the last amplifier stage in response to the voltage of the amplified radio frequency signal being greater than the threshold voltage.

17. The device of claim 16, wherein the control circuit includes a threshold voltage generator circuit configured to generate the threshold voltage.

18. The device of claim 17, wherein the threshold voltage generator circuit includes a variable current source and a variable resistor, the threshold voltage being adjustable based on a variation of the variable current source, the variable resistor, or a combination thereof.

19. The device of claim 17, wherein the control circuit comprises:
a rectifier configured to generate a rectified voltage of the amplified radio frequency signal;
a comparator circuit configured to:
compare the rectified voltage of the amplified radio frequency signal with the threshold voltage, and
generate an output signal in response to the rectified voltage of the amplified radio frequency signal being greater than the threshold voltage; and
a filter circuit configured to remove radio frequencies of the output signal.

20. The device of claim 19, wherein the gain reduction circuit comprises an amplification circuit configured to:
generate an amplified output signal at an output of the filter circuit; and
transfer to an input of the upstream amplifier stage to reduce a gate voltage of an input transistor of the upstream amplifier stage.

21. The device of claim 16, wherein the gain reduction circuit is configured to reduce the gain of the upstream amplifier stage by decreasing a bias voltage of the upstream amplifier stage.

22. The device of claim 16, wherein the first amplifier stage is a driver stage amplifier and the last amplifier stage is a power stage amplifier, the gain reduction circuit configured to reduce the gain of the driver stage amplifier in response to the voltage of the amplified radio frequency signal is greater than the threshold voltage.

23. A power amplifier, comprising:
a first amplifier stage configured to receive an input radio frequency signal;
a last amplifier stage configured to deliver an amplified radio frequency signal, the first amplifier stage and the last amplifier stage arranged in succession to each other; and
a safety circuit, comprising:
a control circuit configured to compare a voltage of the amplified radio frequency signal with a threshold voltage, and
a gain reduction circuit configured to reduce a gain of an upstream amplifier stage to the last amplifier stage in response to the voltage of the amplified radio frequency signal being greater than the threshold voltage.

24. The power amplifier of claim 23, wherein the control circuit includes a threshold voltage generator circuit configured to generate the threshold voltage.

25. The power amplifier of claim 24, wherein the threshold voltage generator circuit includes a variable current source and a variable resistor, the threshold voltage being adjustable based on a variation of the variable current source, the variable resistor, or a combination thereof.

26. The power amplifier of claim 24, wherein the control circuit comprises:
a rectifier configured to generate a rectified voltage of the amplified radio frequency signal;
a comparator circuit configured to:
compare the rectified voltage of the amplified radio frequency signal with the threshold voltage, and
generate an output signal in response to the rectified voltage of the amplified radio frequency signal being greater than the threshold voltage; and
a filter circuit configured to remove radio frequencies of the output signal.

27. The power amplifier of claim 26, wherein the gain reduction circuit comprises an amplification circuit configured to:
generate an amplified output signal at an output of the filter circuit; and
transfer to an input of the upstream amplifier stage to reduce a gate voltage of an input transistor of the upstream amplifier stage.

28. The power amplifier of claim 23, wherein the gain reduction circuit is configured to reduce the gain of the upstream amplifier stage by decreasing a bias voltage of the upstream amplifier stage.
